(19) United States
(12) Patent Application Publication
(10) Pub. No.: US 2026/0371731 A1
(43) Pub. Date: Nov. 19, 2026

(54) DISPLAY PANEL, METHOD FOR DRIVING SAME, AND DISPLAY DEVICE

(71) Applicant: BOE Technology Group Co., Ltd., Beijing (CN)

(72) Inventors: Dongni LIU, Beijing (CN); Zhen ZHANG, Beijing (CN); Zhenyu ZHANG, Beijing (CN); Minghua XUAN, Beijing (CN); Yunsik IM, Beijing (CN); Peirou LI, Beijing (CN)

(21) Appl. No.: 19/145,925

(22) PCT Filed: Aug. 27, 2024
(86) PCT No.: PCT/CN2024/114713

§ 371 Date: Jul. 5, 2025

(30) Foreign Application Priority Data
Jan. 16, 2024 (CN) 202410063895.7

(51) Int. Cl. H10D 86/40; G09G 3/32; G09G 3/3233; H10D 86/60; H10H 29/32; H10H 29/49; H10K 59/121; H10K 59/131; H10K 59/88

(52) U.S. Cl. CPC H10D 86/441; G09G 3/32; G09G 3/3233; H10D 86/60; H10H 29/32; H10H 29/49; H10K 59/1213; H10K 59/1216; H10K 59/131; H10K 59/88; G09G 2300/0408; G09G 2300/0413; G09G 2300/0426; G09G 2300/043; G09G 2300/0819; G09G 2300/0842; G09G 2310/0281; G09G 2320/0261; G09G 2320/045

(57) ABSTRACT

Provided is a display panel, a method for driving the same, and a display device, belonging to the technical field of display technologies. The display panel includes a substrate having a display region and a peripheral region; a plurality of display pixels disposed within the display region; and a light-emitting control circuit disposed within the peripheral region. The display pixels emit light under the driving of signals provided by the signal line, which includes pull-up power lines and pull-down power lines. The light-emitting control circuit responds to light-emitting control signals provided by the light-emitting control line to control the connection or disconnection of the pull-up power line or pull-down power line with the display pixels. Thus, by flexibly arranging the light-emitting control signals, the light-emitting control circuit can flexibly control the duration of connection between the pull-up power line or pull-down power line and the display pixels, thereby flexibly controlling the duration of light emission by the display pixels. As can be known, the display panel exhibits good flexibility in driving the display pixels.

### CROSS-REFERENCE TO RELATED APPLICATION

This application is a U.S. national phase application based on PCT/CN2024/114713, filed on Aug. 27, 2024, which claims priority to Chinese patent Application No. 202410063895.7, filed on Jan. 16, 2024, and entitled “DISPLAY PANEL, METHOD FOR DRIVING SAME, AND DISPLAY DEVICE,” the contents of which are incorporated herein by reference in their entireties.

### TECHNICAL FIELD

The present disclosure relates to the field of display technologies, and in particular, relates to a display panel, a method for driving the same, and a display device.

### BACKGROUND

A display panel typically includes a plurality of pixels, and each of the plurality of pixels includes interconnected pixel circuits and light-emitting units. The pixel circuits are capable of driving the light-emitting units to emit light, thereby causing the display panel to display an image.

In related arts, the pixel circuit typically includes a data write circuit and a light-emitting drive circuit. The data write circuit is connected to a gate line, a data line, and a light-emitting drive circuit, and is configured to control the transmission of data signals from the data line to the light-emitting drive circuit in response to a gate drive signal from the gate line. The light-emitting drive circuit is also connected to a pull-up power line and a light-emitting unit, and is configured to transmit light-emitting drive signals to the light-emitting unit based on data signals and pull-up power signals provided by the pull-up power line. The light-emitting unit is also connected to the pull-down power line, and the light-emitting unit is capable of emitting light under driving by the light-emitting drive signals and the pull-down power signals provided by the pull-down power line.

### SUMMARY

Embodiments of the present disclosure provide a display panel, a method for driving the same, and a display device. The technical solutions are as follows.

In one aspect, a display panel is provided. The display panel includes
a substrate, having a display region and a peripheral region at least partially surrounding the display region;
a plurality of display pixels, arranged in an array within the display region, each of the plurality of display pixels including a data write circuit, a light-emitting drive circuit, an external compensation circuit, and a light-emitting unit, wherein the data write circuit is connected to a gate line, a data line, and an input node, the external compensation circuit is connected to a compensation line, a sensing line, and an output node, the light-emitting drive circuit is connected to the input node, the output node, and a pull-up power line, and the light-emitting unit is connected to the output node and a pull-down power line; and
a plurality of groups of light-emitting control circuits, disposed in the peripheral region, wherein each of the plurality of groups of light-emitting control circuits corresponds to at least one row of a plurality of rows of display pixels, and the plurality of groups of light-emitting control circuits correspond to different rows of display pixels, and each of the plurality of groups of light-emitting control circuits includes light-emitting control circuits disposed on at least one side of the at least one row of display pixels in a row direction, wherein the light-emitting control circuit is connected between a target power line and the at least one row of display pixels, and is connected to a light-emitting control line, and is configured to control connection or disconnection of the target power line to or from the at least one row of display pixels in response to a light-emitting control signal provided by the light-emitting control line;
wherein the target power line is the pull-down power line or the pull-up power line.

In some embodiments, each of the plurality of groups of light-emitting control circuits corresponds to two adjacent rows of display pixels.

In some embodiments, the light-emitting control circuit includes an active layer, a gate metal layer, and a source-drain metal layer that are stacked sequentially on a side of the substrate;
the light-emitting control circuit is connected to the at least one row of display pixels through the source-drain metal layer via a transition via, and the light-emitting control circuit is connected to two display pixels in a same column of the two adjacent rows of display pixels via a same transition via.

In some embodiments, a thickness and a width of the source-drain metal layer satisfy: I_t/(t*b)≤a;
wherein I_t indicates a total pixel current of the plurality of display pixels connected to the light-emitting control circuit, t indicates the thickness of the source-drain metal layer, b indicates the width of the source-drain metal layer, and a indicates a maximum current density of a portion of the source-drain metal layer disposed in the transition via.

In some embodiments, each of the plurality of groups of light-emitting control circuits includes two light-emitting control circuits disposed on both sides of the at least one row of display pixels in the row direction respectively.

In some embodiments, one light-emitting control circuit disposed on one side is connected to a portion of the display pixels in the at least one row of display pixels, and the other light-emitting control circuit disposed on the other side is connected to another portion of the display pixels in the at least one row of display pixels.

In some embodiments, the light-emitting control circuit includes a light-emitting control transistor;
a gate electrode of the light-emitting control transistor is connected to the light-emitting control line, a first electrode of the light-emitting control transistor is connected to the target power line, and a second electrode of the light-emitting control transistor is connected to the at least one row of display pixels.

In some embodiments, the light-emitting control transistor is an N-type transistor.

In some embodiments, the light-emitting control transistor is a dual-gate transistor.

In some embodiments, the data write circuit includes a data write transistor;
wherein a gate electrode of the data write transistor is connected to the gate line, a first electrode of the data write transistor is connected to the data line, and a second electrode of the data write transistor is connected to the input node.

In some embodiments, the external compensation circuit includes a compensation transistor;
wherein a gate electrode of the compensation transistor is connected to the compensation line, a first electrode of the compensation transistor is connected to the sensing line, and a second electrode of the compensation transistor is connected to the output node.

In some embodiments, the light-emitting drive circuit includes a drive transistor; wherein
in a case that the target power line is the pull-up power line, a gate electrode of the drive transistor is connected to the input node, a first electrode of the drive transistor is connected to a transition node, a second electrode of the drive transistor is connected to a first electrode of the light-emitting unit, and a second electrode of the light-emitting unit is connected to the pull-down power line;
in a case where the target power line is the pull-down power line, the gate electrode of the drive transistor is connected to the input node, the first electrode of the drive transistor is connected to the pull-up power line, the second electrode of the drive transistor is connected to the first electrode of the light-emitting unit, and the second electrode of the light-emitting unit is connected to the transition node; and
the light-emitting control circuit is connected to the transition node.

In some embodiments, any one of the data write transistors of the data write circuit, the compensation transistor of the external compensation circuit, and the drive transistor of the light-emitting drive circuit is an N-type transistor or a P-type transistor.

In some embodiments, each of the plurality of display pixels further includes a storage capacitor; wherein
in a case where the drive transistor is a P-type transistor, the target power line is the pull-down power line, and the storage capacitor is connected in series between the input node and the pull-up power line; or
in a case where the drive transistor is an N-type transistor, the target power line is the pull-up power line, and the storage capacitor is connected in series between the input node and the output node.

In some embodiments, the display panel further includes a plurality of dummy pixels disposed in the display region between the plurality of rows of display pixels and the plurality of groups of light-emitting control circuits.

In some embodiments, a material of the N-type transistor of the display panel includes an oxide material, and a material of the P-type transistors of the display panel includes a low-temperature polysilicon material.

In another aspect, a method for driving a display panel is provided, and the method is configured to drive the display panel in the above aspect. The method includes
a write stage, wherein the potential of the light-emitting control signal provided by the light-emitting control line is a first potential, and in response to the light-emitting control signal at the first potential, the light-emitting control circuit controls the target power line to be disconnected from the display pixel; and
a light-emitting stage, wherein the potential of the light-emitting control signal provided by the light-emitting control line is a second potential, and in response to the light-emitting control signal at the second potential, the light-emitting control circuit controls the target power line to be connected to the display pixel;
wherein the target power line is the pull-up power line connected to the light-emitting drive circuit of the display pixel, or the target power line is the pull-down power line connected to the light-emitting unit of the display pixel.

In still another aspect, a display device is provided. The display device includes a light-emitting control drive circuit and the display panel described in the above aspect;
wherein the light-emitting control drive circuit is connected to a plurality of light-emitting control lines connected to a plurality of light-emitting control circuits of the display panel, and is configured to transmit light-emitting control signals to the plurality of light-emitting control lines.

In some embodiments, the light-emitting control drive circuit is disposed in a peripheral region of a substrate of the display panel, and the light-emitting control drive circuit includes a plurality of cascaded light-emitting control drive units, wherein the plurality of light-emitting control drive units are connected in one-to-one correspondence with the plurality of light-emitting control lines, and are configured to sequentially transmit the light-emitting control signals to the plurality of light-emitting control lines.

In some embodiments, the light-emitting control drive circuit is independent of the display panel, and the light-emitting control drive circuit is configured to simultaneously transmit the light-emitting control signals to the plurality of light-emitting control lines.

### BRIEF DESCRIPTION OF DRAWINGS

For clearer descriptions of the technical solutions according to the embodiments of the present disclosure, the following briefly introduces the accompanying drawings required for describing the embodiments. Apparently, the accompanying drawings in the following description show merely some examples of the present disclosure, and those of ordinary skill in the art may still derive other drawings from these accompanying drawings without creative efforts.

FIG. 1 is a schematic structural diagram of a display panel according to some embodiments of the present disclosure;

FIG. 2 is a schematic structural diagram of a display pixel and light-emitting control circuit according to some embodiments of the present disclosure;

FIG. 3 is another schematic structural diagram of a display pixel and light-emitting control circuit according to some embodiments of the present disclosure;

FIG. 4 is another schematic structural diagram of a display panel according to some embodiments of the present disclosure;

FIG. 5 is a schematic structural diagram of the circuit of a display panel according to some embodiments of the present disclosure;

FIG. 6 is a schematic structural diagram of the circuit of another display panel according to some embodiments of the present disclosure;

FIG. 7 is a schematic structural diagram of the circuit of still another display panel according to some embodiments of the present disclosure;

FIG. 8 is a schematic structural diagram of the circuit of still another display panel according to some embodiments of the present disclosure;

FIG. 9 is a schematic layout diagram of a display panel according to some embodiments of the present disclosure;

FIG. 10 is a schematic structural layout diagram of another display panel according to some embodiments of the present disclosure;

FIG. 11 is a schematic diagram of the characteristic curve of a light-emitting control circuit according to some embodiments of the present disclosure;

FIG. 12 is a flowchart diagram of a method for driving a display panel according to some embodiments of the present disclosure;

FIG. 13 is a schematic diagram of the signal timing of a display panel according to some embodiments of the present disclosure;

FIG. 14 is a schematic diagram of the signal timing of another display panel according to some embodiments of the present disclosure;

FIG. 15 is a schematic diagram of the signal timing of still another display panel according to some embodiments of the present disclosure;

FIG. 16 is a schematic structural diagram of a display device according to some embodiments of the present disclosure; and

FIG. 17 is a schematic structural diagram of another display device according to some embodiments of the present disclosure.

### DETAILED DESCRIPTION

For clearer descriptions of the objectives, technical solutions, and advantages of the present disclosure, the embodiments of the present disclosure are further described in detail below referring to the accompanying drawings.

It should be noted that the transistors in all embodiments of the present disclosure may be thin-film transistors, field-effect transistors, or other devices with equivalent characteristics. Because the source and the drain of the transistors used here are symmetrical, the source and the drain are interchangeable. The source is referred to as the first electrode and the drain is referred to as the second electrode, or the drain is referred to as the first electrode and the source is referred to as the second electrode. As shown in the attached figures, the middle electrode of the transistor is defined as the gate, the signal input electrode is defined as the source, and the signal output electrode is defined as the drain. Additionally, the transistors in the embodiments of this disclosure may include either P-type transistors or N-type transistors, or a combination thereof. The P-type transistors conduct when the gate is at a low voltage and cut off when the gate is at a high voltage, while N-type transistors conduct when the gate is at a high voltage and cut off when the gate is at a low voltage. Furthermore, each of a plurality of signals in the embodiments correspond to a first potential or a second potential. The first potential and second potential merely represent that the signal has two different potential states and do not represent specific numerical values for the first or second potential.

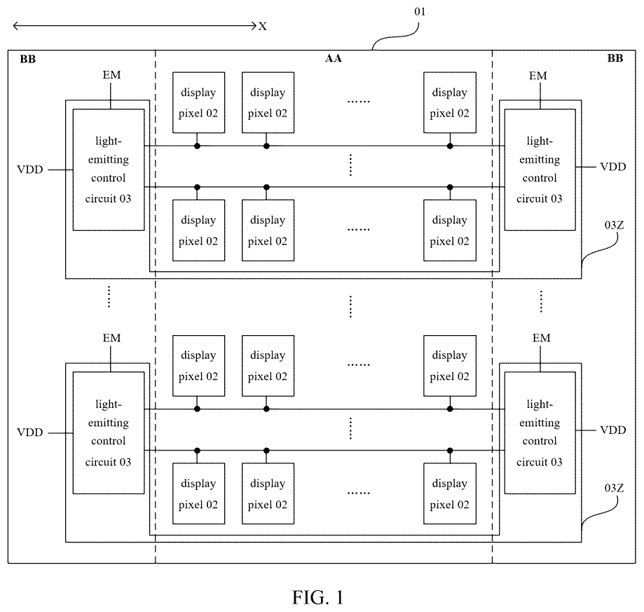

FIG. 1 is a structural schematic diagram of a display panel according to some embodiments of the present disclosure. As shown in FIG. 1, the display panel includes a substrate 01, which has a display region AA and a peripheral region BB at least partially surrounding the display region AA.

For example, the display region AA shown in FIG. 1 is rectangular, and the peripheral region BB is located on the left and right sides of the display region AA, partially surrounding the display region AA. In some embodiments, the display region AA may also have other shapes, such as a circular shape, and the peripheral region BB may be located on all sides of the display region AA, i.e., surrounding the display region AA.

It should be understood that the display region AA is capable of displaying images, while the peripheral region BB is not capable of displaying images. The peripheral region BB may also be referred to as the non-display region. Furthermore, the area of display region AA is generally much larger than the area of the non-display region BB, and the figures are merely illustrative.

Referring to FIG. 1, the display panel further includes a plurality of display pixels 02 arranged in an array, wherein the plurality of display pixels 02 are disposed within the display region AA. The array arrangement refers to a row-and-column arrangement, i.e., the display panel includes a plurality of rows and columns of display pixels 02.

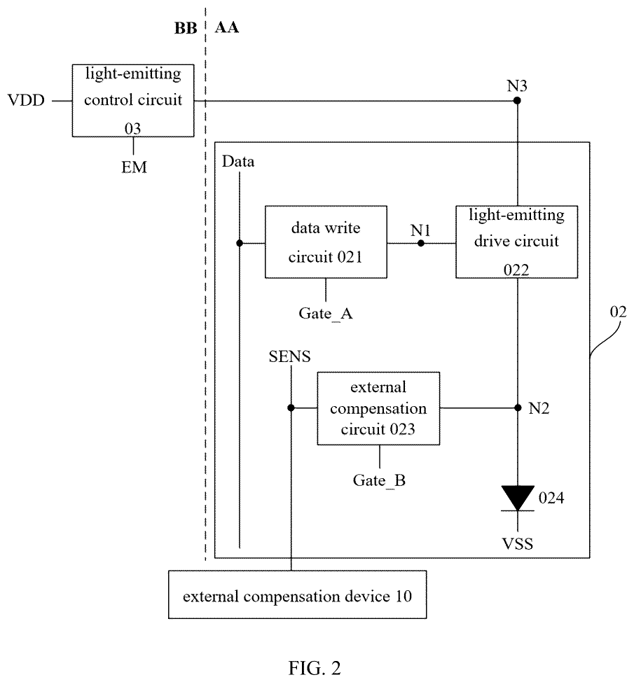

Based on FIG. 1, referring to FIG. 2, it can be seen that each display pixel 02 includes a data write circuit 021, a light-emitting drive circuit 022, an external compensation circuit 023, and a light-emitting unit 024. The data write circuit 021, the light-emitting drive circuit 022, and the external compensation circuit 023 can collectively be referred to as the pixel circuit.

The data write circuit 021 is connected to the gate line Gate_A, the data line Data, and the input node N1. The external compensation circuit 023 is connected to the compensation line Gate_B, the sensing line SENS, and the output node N2. The light-emitting drive circuit 022 is connected to input node N1, output node N2, and pull-up power line VDD. The light-emitting unit 024 is connected to output node N2 and pull-down power line VSS.

Optionally, the light-emitting unit 024 may be an organic light-emitting diode (OLED). Additionally, as shown in FIG. 2, the first electrode (e.g., anode) of the light-emitting unit 024 may be connected to the output node N2, and the second electrode (e.g., cathode) of the light-emitting unit 024 may be connected to the pull-down power line VSS.

The data write circuit 021 can control connection or disconnection of the data line Data to or from the input node N1 in response to the gate drive signal provided by the gate line Gate_A. For example, the data write circuit 021 can disconnect the data line Data from the input node N1 in the case that the gate drive signal is at the first potential, and can connect the data line Data to the input node N1 in the case that the gate drive signal is at the second potential, which causes the data signal provided by the data line Data to be transmitted to the input node N1.

The light-emitting drive circuit 022 can transmit a light-emitting drive signal (e.g., pixel current) to the output node N2 based on the potential of the input node N1 and the pull-up power signal provided by the pull-up power line VDD, enabling the light-emitting unit 024 to emit light based on the light-emitting drive signal and the pull-down power signal provided by the pull-down power line VSS.

External compensation circuit 023 controls connection or disconnection of sensing line SENS of or from output node N2 in response to the compensation signal provided by compensation line Gate_B. Additionally, as shown in FIG. 2, the sensing line SENS is connected to an external compensation device 10. For example, the external compensation circuit 023 controls the sensing line SENS to disconnect from the output node N2 in the case that the potential of the compensation signal is at the first potential, and controls the sensing line SENS to connect to the output node N2 in the case that the potential of the compensation signal is at the second potential, which causes the sensing line SENS to transmit the reference signal provided by the external compensation device 10 to the output node N2 to reset the output node N2, or causes the sensing line SENS to collect the potential of the output node N2 and transmit the potential of the output node N2 to the external compensation device 10, such that the external compensation device 10 extracts sensing signals such as the threshold voltage Vth of the drive transistor of the light-emitting drive circuit 022 and the pixel current transmitted by the light-emitting drive circuit 022 to the light-emitting unit 024, and performs external compensation on the data signal provided by the data line Data based on the extracted sensing signals, ensuring that the light-emitting unit 024 emits light reliably.

Referring to FIG. 1, the display panel further includes a plurality of groups of light-emitting control circuits 03Z, which are disposed within the peripheral region BB. Each of the plurality of groups of light-emitting control circuits 03Z corresponds to at least one row of display pixels 02 of the plurality of rows of display pixels 02, and each of the plurality of groups of light-emitting control circuits 03Z corresponds to different rows of display pixels 02. Additionally, each of the plurality of groups of light-emitting control circuits 03Z includes light-emitting control circuits 03 disposed on at least one side of the corresponding at least one row of display pixels 02 in the row direction X. The light-emitting control circuit 03 is connected between the target power line and at least one row of display pixels 02, and is also connected to the light-emitting control line EM, and is configured to control connection or disconnection of the target power line to or from at least one row of display pixels 02 in response to the light-emitting control signal provided by the light-emitting control line EM.

For example, the light-emitting control circuit 03 disconnects the target power line from at least one row of display pixels 02 in the case that the voltage of the light-emitting control signal provided by the light-emitting control line EM is at a first voltage, and controls the target power line to be connected to at least one row of display pixels 02 in the case that the voltage of the light-emitting control signal is at a second voltage, such that the power signal provided by the target power line is transmitted to the display pixels 02, thereby driving the display pixels 02 to emit light reliably. The target power line is either the pull-down power line VSS or the pull-up power line VDD. The target power line shown in FIG. 1 is the pull-up power line VDD.

As shown in FIG. 2, in an implementation, the target power line is the pull-up power line VDD, that is, the light-emitting drive circuit 022 in display pixel 02 is indirectly connected to the pull-up power line VDD via the light-emitting control circuit 03, and the connection point is also referred to as the transition node N3. The light-emitting control circuit 03 controls the connection or disconnection of the pull-up power line VDD to or from the light-emitting drive circuit 022 under the control of the light-emitting control signal provided by the light-emitting control line EM. As described above, in the case that the light-emitting control circuit 03 controls the pull-up power line VDD to be connected to the light-emitting drive circuit 022, the light-emitting drive circuit 022 transmits a light-emitting drive signal to the first electrode of the light-emitting unit 024 based on the potential of the input node N1 and the pull-up power signal provided by the pull-up power line VDD, thereby driving the light-emitting unit 024 to emit light.

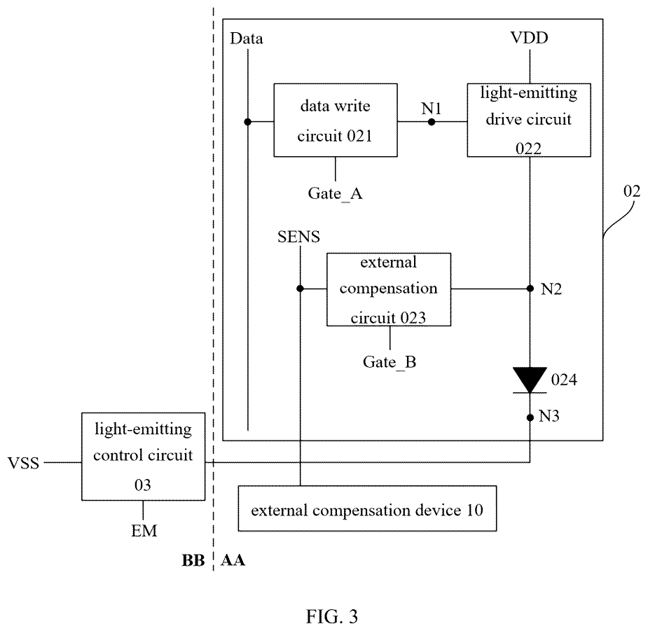

Alternatively, as shown in FIG. 3, in another implementation, the target power line is the pull-down power line VSS. That is, the second electrode of the light-emitting unit 024 of the display pixel 02 is indirectly connected to the pull-down power line VSS through the light-emitting control circuit 03, and the connection point is also referred to as the transition node N3. The light-emitting control circuit 03 controls the connection between the pull-down power line VSS and the second electrode of the light-emitting unit 024 under the control of the light-emitting control signal provided by the light-emitting control line EM. As described above, in the case that the light-emitting control circuit 03 controls the pull-down power line VSS to be connected to the second electrode of the light-emitting unit 024, the light-emitting unit 024 emits light based on the light-emitting drive signal transmitted by the light-emitting drive circuit 022 and the pull-down power signal provided by the pull-down power line VSS.

Therefore, by flexibly arranging the light-emitting control signal, the light-emitting control circuit 03 flexibly controls the duration of power signal transmission from the pull-up power line VDD or the pull-down power line VSS to the display pixel 02, thereby achieving the purpose of flexibly controlling the duty of the light-emitting duration of the light-emitting unit 024. Based on this, display abnormalities such as motion blur is effectively improved, which ensures good display performance of the display panel.

Additionally, in the present disclosure, for display pixels 02 with external compensation functionality, the light-emitting control circuit 03 is disposed within the peripheral region BB rather than the display region AA. That is, the light-emitting control circuit 03 is an external circuit relative to the pixel circuit of the display pixel 02. Therefore, compared to the implementation that the display pixel 02 includes a light-emitting control circuit disposed within the display region AA, the solution provided by the present disclosure does not increase the dimension of the display pixel 02 (i.e., pixel pitch), thereby avoiding a reduction in the PPI (pixels per inch) of display region AA, and facilitating the design of a display panel with high PPI. Wherein, PPI refers to the number of pixels that can be set within one inch of the display panel, used to characterize resolution.

Optionally, the first potential refers to an inactive potential, and the second potential refers to an active potential. For the N-type transistors of each circuit, the inactive potential is a low-potential relative to the active potential. For the P-type transistors of each circuit, the inactive potential is a high-potential relative to the active potential.

In summary, embodiments of the present disclosure provide a display panel. The display panel includes a substrate having a display region and a peripheral region, a plurality of display pixels disposed within the display region, and a light-emitting control circuit disposed within the peripheral region. The display pixels emit light under the signal drive provided by the signal line, which includes a pull-up power line and a pull-down power line. The light-emitting control circuit, in response to light-emitting control signals provided by light-emitting control lines, controls the connection or disconnection of the pull-up power line or pull-down power line with the display pixels. Thus, by flexibly arranging the light-emitting control signals, the light-emitting control circuit flexibly controls the duration of the pull-up power line or pull-down power line being connected to the display pixels, thereby flexibly controlling the light-emitting duration of the display pixel. As can be known, the display panel exhibits good flexibility in driving the display pixels.

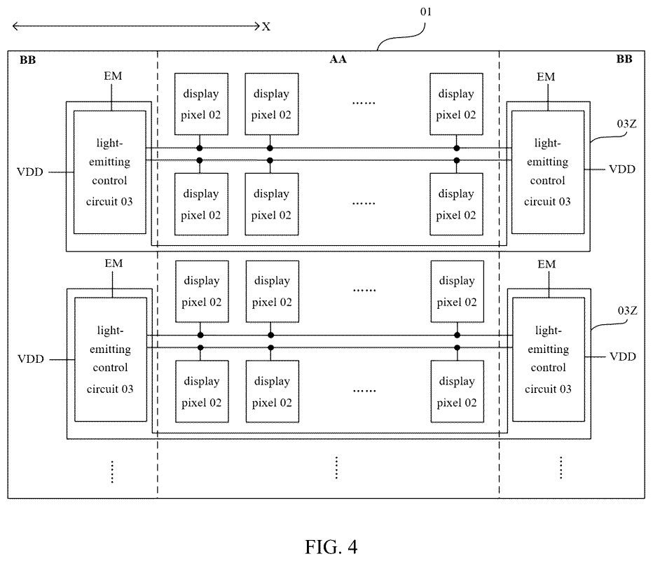

Optionally, FIG. 4 is a structural schematic diagram of another display panel according to some embodiments of the present disclosure. As shown in FIG. 4, each of the plurality of groups of light-emitting control circuits 03Z corresponds to two adjacent rows of display pixels 02.

For example, referring to FIG. 4, from top to bottom, the first row of display pixels 02 and the second row of display pixels 02 are connected to each light-emitting control circuit 03 included in the same group of light-emitting control circuits 03Z. The third row of display pixels 02 and the fourth row of display pixels 02 are connected to each light-emitting control circuit 03 included in the same group of light-emitting control circuits 03Z. In this way, not only is wiring facilitated, but also a smaller number of light-emitting control circuits 03 need to be provided, thereby facilitating a narrow bezel design for the display panel.

Optionally, as shown in FIGS. 1 and 4, in the embodiments of the present disclosure, each of the plurality of groups of light-emitting control circuits 03Z includes two light-emitting control circuits 03 disposed on both sides of at least one row of display pixels 02 in the row direction X respectively. That is, each of the plurality of groups of light-emitting control circuits 03Z includes one light-emitting control circuit 03 disposed on the left side of the display region AA as shown in the figure, and the other light-emitting control circuit 03 is disposed on the right side of the display region AA as shown in the figure, totaling two light-emitting control circuits 03.

Furthermore, one light-emitting control circuit 03 disposed on one side is connected to a portion of the display pixels 02 of at least one row of display pixels 02, while the other light-emitting control circuit 03 disposed on the other side is connected to another portion of the display pixels 02 of at least one row of display pixels 02, excluding the above portion of display pixels 02.

Therefore, in the row direction X, for display pixels 02 close to the left side of display region AA and display pixels 02 close to the right side of display region AA, the light-emitting control circuit 03 promptly controls the connection or disconnection of target power lines such as pull-up power line VDD or pull-down power line VSS with display pixels 02. Furthermore, the longer the trace connecting the light-emitting control circuit 03 to the display pixels 02 is, the higher the impedance on the trace is, which leads to poor reliability of the power signal transmitted from the target power lines to the display pixels 02. By configuring one light-emitting control circuit 03 on each side in the row direction X, the length of the traces connected to each light-emitting control circuit 03 is reduced, thereby lowering the impedance on the traces, which ensures reliable transmission of the power signal from the target power line to display pixel 02. In some embodiments, for scenarios with high impedance, increasing the trace width is considered to reduce impedance. However, the scheme of the embodiments of the present disclosure does not require increasing the trace width, which is advantageous for high PPI design of the display panel.

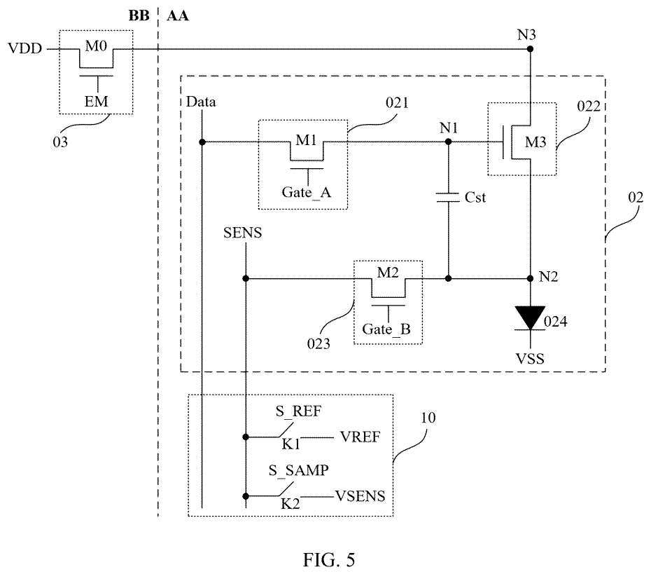

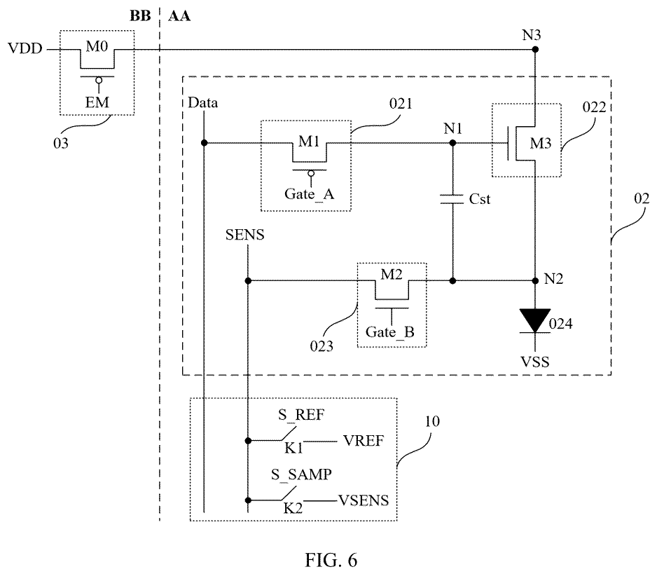

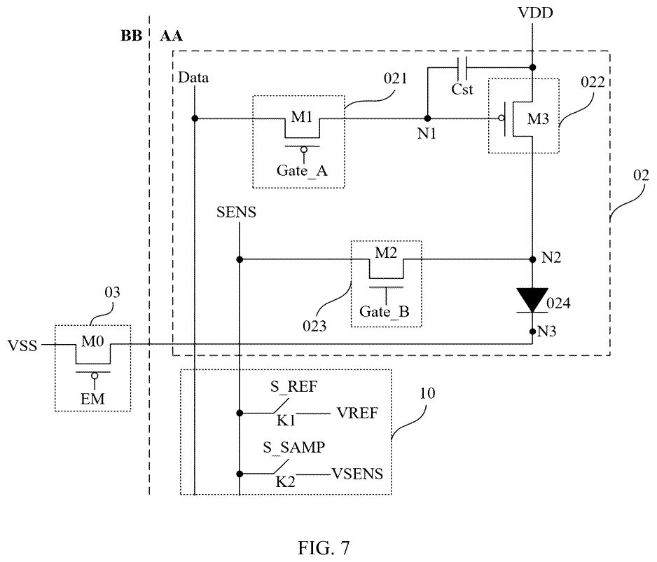

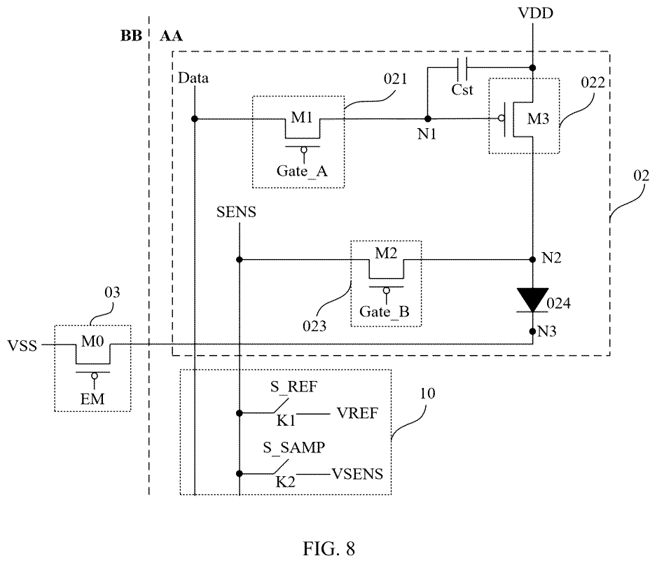

Optionally, in conjunction with FIG. 2, FIG. 5 illustrates schematic structural diagram of the circuit of a display panel. FIG. 6 illustrates a schematic structural diagram of the circuit of another display panel. In conjunction with FIG. 3, FIG. 7 illustrates a schematic structural diagram of the circuit of still another display panel. FIG. 8 illustrates a schematic structural diagram of the circuit of still another display panel. Referring to FIGS. 5 to 8, it can be seen that the light-emitting control circuit 03 includes a light-emitting control transistor M0.

The gate electrode of the light-emitting control transistor M0 is connected to the light-emitting control line EM, the first electrode of the light-emitting control transistor M0 is connected to the target power line, and the second electrode of the light-emitting control transistor M0 is connected to at least one row of display pixels 02, i.e., connected to the transition node N3. For example, the target power line shown in FIGS. 5 and 6 is the pull-up power line VDD, and the target power line shown in FIGS. 7 and 8 is the pull-down power line VSS.

Optionally, as shown in FIG. 5, the light-emitting control transistor M0 is an N-type transistor. In other embodiments, as shown in FIGS. 6 to 8, the light-emitting control transistor M0 is a P-type transistor.

Optionally, in the embodiments of the present disclosure, the light-emitting control transistor M0 is also a dual-gate transistor. That is, the light-emitting control transistor M0 has two gates.

Because the leakage current of a P-type transistor is generally larger, arranging the light-emitting control transistor M0 as an N-type transistor can reduce the leakage current of the light-emitting control transistor M0, which ensures reliable transmission of the power signal to the display pixel 02. Additionally, in the case that the light-emitting control transistor M0 is configured as a dual-gate transistor, the threshold voltage Vth of the light-emitting control transistor M0 can be stabilized, which further ensures reliable transmission of power signals to the display pixel 02.

Optionally, as shown in FIGS. 5 to 8, the data write circuit 021 includes a data write transistor M1. The external compensation circuit 023 includes a compensation transistor M2. The light-emitting drive circuit 022 includes a drive transistor M3.

The gate electrode of the data write transistor M1 is connected to the gate line Gate_A, the first electrode of the data write transistor M1 is connected to the data line Data, and the second electrode of the data write transistor M1 is connected to the input node N1.

The gate electrode of the compensation transistor M2 is connected to the compensation line Gate_B, the first electrode of the compensation transistor M2 is connected to the sensing line SENS, and the second electrode of the compensation transistor M2 is connected to the output node N2.

In the case that the target power line is the pull-up power line VDD, as shown in FIGS. 5 and 6, the gate electrode of the drive transistor M3 is connected to the input node N1, the first electrode of the drive transistor M3 is connected to the intermediate node N3, the second electrode of the drive transistor M3 is connected to the first electrode of the light-emitting unit 024, and the second electrode of the light-emitting unit 024 is connected to the pull-down power line VSS.

In the case that the target power line is the pull-down power line VSS, as shown in FIGS. 7 and 8, the gate electrode of the drive transistor M3 is connected to the input node N1, the first electrode of the drive transistor M3 is connected to the pull-up power line VDD, the second electrode of the drive transistor M3 is connected to the first electrode of the light-emitting unit 024, and the second electrode of the light-emitting unit 024 is connected to the transition node N3.

The light-emitting control circuit 03 is connected to the transition node N3. That is, as described above, the second electrode of the light-emitting control transistor M0 is connected to the display pixel 02 by being connected to the transition node N3.

Optionally, any of the data write transistor M1 in the data write circuit 021, the compensation transistor M2 in the external compensation circuit 023, or the drive transistor M3 in the light-emitting drive circuit 022 is an N-type transistor or a P-type transistor.

For example, as shown in FIG. 5, the circuit structure illustrated therein includes a data write transistor M1, a compensation transistor M2, and a drive transistor M3, all of which are N-type transistors. As shown in FIG. 6, the circuit structure illustrated therein includes a data write transistor M1, which is a P-type transistor, and a compensation transistor M2 and a drive transistor M3, both of which are N-type transistors. Referring to FIG. 7, the circuit structure illustrated therein includes a data write transistor M1 and a drive transistor M3, both of which are P-type transistors, and a compensation transistor M2, which is an N-type transistor. Referring to FIG. 8, the circuit structure illustrated therein includes a data write transistor M1, a compensation transistor M2, and a drive transistor M3, all of which are P-type transistors.

Optionally, in the embodiments of the present disclosure, the material of the P-type transistor in the display panel includes low temperature poly-silicon (LTPS) material. The material of the N-type transistor in the display panel includes oxide material. Based on this, the circuit structure shown in FIG. 5 is referred to as a fully N-type oxide architecture pixel circuit. The circuit structures illustrated in FIGS. 6 and 7 are referred to as pixel circuits with a low temperature poly-silicon oxide (LTPO) architecture that includes both P-type transistors and N-type transistors. The circuit structure illustrated in FIG. 8 is referred to as a pixel circuit with a fully P-type LTPS architecture.

Among these, the LTPO architecture shown in FIGS. 6 and 7 simultaneously utilizes the advantages of the low leakage current of N-type transistors made of oxides and the mobility of P-type transistors made of LTPS, resulting in better operational reliability.

Optionally, the transistors described in the embodiments of this disclosure are all metal oxide semiconductor (MOS) field-effect transistors.

Optionally, as shown in FIGS. 5 and 8, the display pixel 02 further includes a storage capacitor Cst. The storage capacitor Cst is configured to store signals.

In the case that the drive transistor M3 is a P-type transistor, as shown in FIGS. 7 and 8, the target power line is the pull-down power line VSS, i.e., the first electrode of the light-emitting control transistor M0 is connected to the pull-down power line VSS, the second electrode of the light-emitting control transistor M0 is connected to the second electrode of the light-emitting unit 024 via the connection node N3. Additionally, the storage capacitor Cst is connected in series between the input node N1 and the pull-up power line VDD.

In the case that the drive transistor M3 is an N-type transistor, as shown in FIGS. 5 and 6, the target power line is the pull-up power line VDD, i.e., the first electrode of the light-emitting control transistor M0 is connected to the pull-up power line VDD, and the second electrode of the light-emitting control transistor M0 is connected to the first electrode of the drive transistor M3 via the transition node N3. Additionally, the storage capacitor Cst is connected in series between the input node N1 and the output node N2.

For some embodiments where the drive transistor M3 is a P-type transistor, by arranging the target power line as the pull-down power line VSS, i.e., configuring the light-emitting control transistor M0 to indirectly connect the pull-down power line VSS to the second electrode of the light-emitting unit 024, it is possible to flexibly control the light-emitting duration, while reducing current differences caused by voltage drop at the source of the drive transistor M3, which ensures that the drive transistor M3 reliably transmits the light-emitting drive signal to the light-emitting unit 024 to drive the light-emitting unit 024 to reliably emit light.

It should be understood that in the circuit structures shown in FIGS. 5 to 8, the pixel circuits of the display pixel 02 are all considered to be 3T1C structure circuits including three transistors and one storage capacitor. In some other embodiments, it can also be a 2T1C structure circuit.

Optionally, as shown in FIGS. 5 to 8, the external compensation device 10 described above further includes a switch K1 and a switch K2.

The witch K1 is connected between the reference signal terminal V_REF and the sensing line SENS, and is connected to the switch control terminal S_REF, and is configured to control the connection or disconnection of the reference signal terminal V_REF to or from the sensing line SENS in response to the switch control signal provided by the switch control terminal S_REF.

For example, in the case that the potential of the switch control signal provided by the switch control terminal S_REF is at an effective potential, the switch K1 controls the reference signal terminal V_REF and the sensing line SENS to be conductive, such that the reference signal terminal V_REF transmits the reference signal described above to the output node N2 through the sensing line SENS. In the case that the potential of the switch control signal provided by the switch control terminal S_REF is an invalid potential, the switch K1 controls the reference signal terminal V_REF and the sensing line SENS to be disconnected.

The switch K2 is connected between the test terminal VSENS and the sensing line SENS, and is connected to the switch control terminal S_SAMP, and is configured to control the connection or disconnection of the test terminal VSENS and the sensing line SENS in response to the switch control signal provided by the switch control terminal S_SAMP.

For example, the switch K2 controls the test terminal VSENS and the sensing line SENS to be conductive in the case that the potential of the switch control signal provided by the switch control terminal S_SAMP is a valid potential, such that the test terminal VSENS collects the sensing signal described above through the sensing line SENS. In the case that the potential of the switch control signal provided by the switch control terminal S_SAMP is an invalid potential, the switch K2 controls the test terminal VSENS and the sensing line SENS to be disconnected.

Optionally, as shown in FIGS. 5 to 8, the switches K1 and K2 are both single-pole single-throw switches. For any switch, in the case that the potential of the switch control signal received by the switch is an effective potential, the switch is close. In the case that the potential of the switch control signal received by the switch is an ineffective potential, the switch is open. In some other embodiments, the switch K1 and/or switch K2 are also the transistors described above.

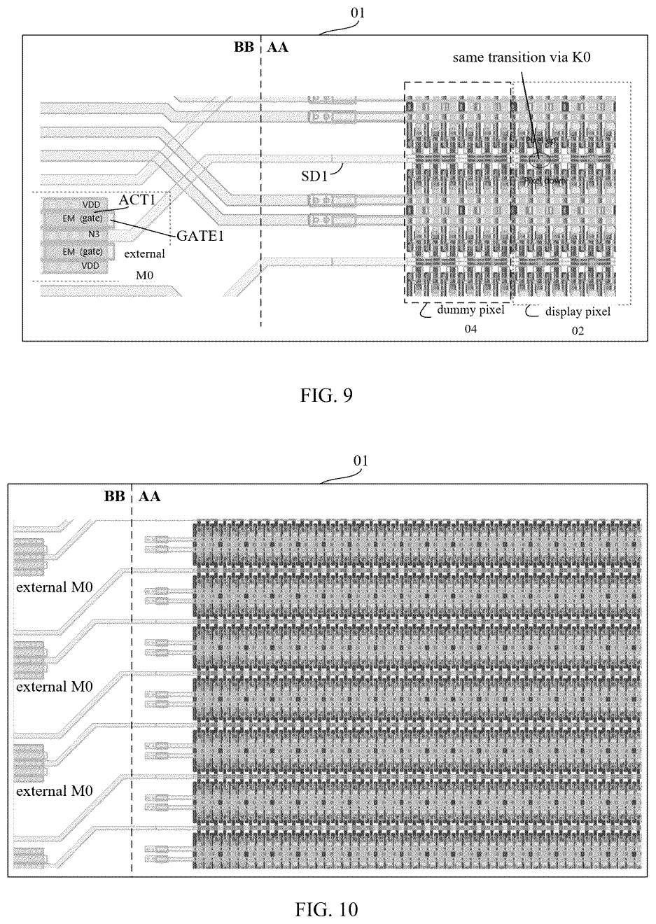

Optionally, in combination with the structure shown in FIG. 4, FIG. 9 illustrates schematic layout diagram of a display panel. As shown in FIG. 9, the light-emitting control circuit 03 (i.e., the light-emitting control transistor M0 mounted on the peripheral region BB) includes an active (ACT) layer ACT1, a gate metal layer GATE1, and a source-drain (SD) metal layer SD1, which are stacked sequentially on a side of the substrate 01.

The light-emitting control circuit 03 is connected to at least one row of display pixels 02 through the source-drain metal layer SD1 via a transition via K0. Additionally, the light-emitting control circuit 03 is connected to two display pixels 02 in the same column of adjacent rows of display pixels 02 via the same transition via K0. This ensures reliable interconnection between the light-emitting control circuit 03 and the display pixels 02 while simplifying the process and reducing costs.

For example, for an implementation that the target power line is the pull-up power line VDD, the light-emitting control transistor M0 is connected to the first electrode of the drive transistor M3 of the display pixel 02, as shown in FIG. 9, the source-drain metal layer SD1 of the light-emitting control transistor M0 is connected to the active layer ACT1 of the drive transistor M3. That is, the active layers ACT1 of the drive transistors M3 in the adjacent upper and lower rows of display pixels is connected to the source-drain metal layer SD1 of the light-emitting control transistor M0 via the same transition via K0.

For example, for the implementation that the target power line is the pull-down power line VSS, the light-emitting control transistor M0 is connected to the second electrode of the light-emitting unit 024 in the display pixel 02. Assuming that the second electrode of the light-emitting unit 024 is the cathode, it can be considered that the source-drain metal layer SD1 of the light-emitting control transistor M0 is connected to the cathode of the light-emitting unit 024. That is, the cathodes of the light-emitting units 024 in the adjacent upper and lower rows of display pixels are connected to the source-drain metal layer SD1 of the light-emitting control transistor M0 via the same transition via K0.

Additionally, as shown in FIG. 9, the light-emitting control transistor M0 has two gates, and is a dual-gate transistor.

Optionally, as shown in FIG. 9, the display panel further includes a plurality of dummy pixels 04, which are disposed within the display region AA and between the plurality of rows of display pixels 02 and the plurality of groups of light-emitting control circuits 03Z (i.e., external light-emitting control transistors M0). In this way, good etching uniformity during the fabrication of the display panel is ensured. Optionally, based on the layout shown in FIG. 9, FIG. 10 further schematically illustrates a structural layout including a plurality of rows of display pixels 02.

It should be understood that the pull-up power line VDD or the pull-down power line VSS is connected to a plurality of display pixels 02 via a light-emitting control transistor M0, and transmits power signals to a plurality of display pixels 02. Therefore, it is known that the on-state current of the light-emitting control transistor M0 needs to be relatively large. Furthermore, it cis known that the width and film thickness of the metal trace at the interface node N3 (i.e., the trace formed by the source-drain metal layer SD1 of the light-emitting control transistor M0) must meet the maximum current density corresponding to the large current to reduce the issue of trace heating.

Therefore, in the embodiments of the present disclosure, the thickness and width of the source-drain metal layer SD1 of the light-emitting control transistor M0 satisfies: I_t/(t*b)≤a.

Wherein I_t indicates the total pixel current of a plurality of display pixels 02 connected to each light-emitting control circuit 03, t indicates the thickness of the source-drain metal layer SD1, b indicates the width of the source-drain metal layer SD1, and a indicates the maximum current density of the portion of the source-drain metal layer SD1 disposed in the transition via K0 (i.e., transition node N3).

Assuming that the unit of I_t is microamperes (μA), the unit of a is milliamps per square micrometer (mA/μm²), the unit of b is μm, and the unit of t is μm, upon converting the units, it can be derived that the line width b of the source-drain metal layer SD1 satisfies: b≥I_t/1000/(t*a).

Furthermore, it is understood that the on-state current of the light-emitting control transistor M0 should also be greater than or equal to I_t, i.e., satisfy the total sum of the maximum currents of all controlled display pixels. In some embodiments, the on-state current of the light-emitting control transistor M0 is increased by increasing the width-to-length ratio W/L or the source-drain current Vds of the light-emitting control transistor M0.

For example, assuming that the pixel current of each display pixel is Id (μA), the light-emitting control transistor M0 is connected to n rows of display pixels 02 to control the transmission of power signals from the target power line to those n rows of display pixels 02, and each row of display pixels 02 includes m display pixels, then I_t satisfies: I_t=Id*n*m.

Wherein n is an integer greater than or equal to 1 and less than the number of rows of display pixels 02, and m is an integer greater than 1 and less than the number of columns of display pixels 02.

Taking an OLED display product as an example, assuming the horizontal resolution H=2000, i.e., the display panel includes 2000 columns of display pixels 02, Id=150 nA, and a group of light-emitting control circuits 03Z includes one light-emitting control circuit 03 on each side, with each light-emitting control circuit 03 connected to one row of display pixels 02, i.e., n=1, m=H/2=1000, then the following is calculated: I_t=150 μA. That is, the on-state current of the light-emitting control transistor M0 in each light-emitting control circuit 03 must be at least 150 μA.

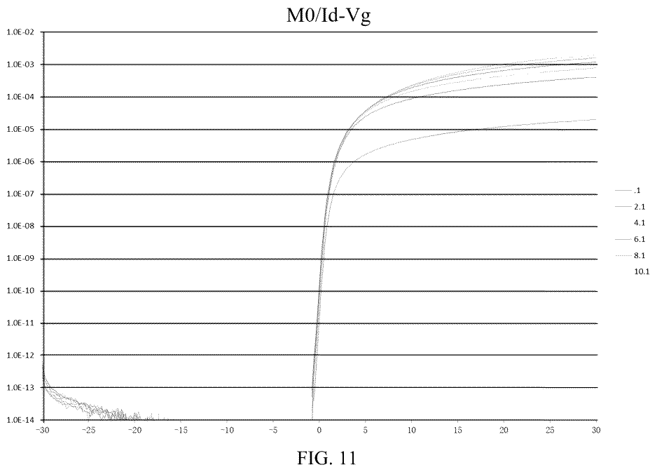

Optionally, FIG. 11 schematically illustrates the characteristic curves of the light-emitting control transistor M0 under different on-state currents (e.g., 1, 2.1, 4.1, etc.). The horizontal axis represents current, and the vertical axis represents voltage.

It should be understood that the light-emitting control transistor M0 described in the embodiments of the present disclosure is not only applicable to OLED display products that the light-emitting unit 024 is an OLED, but also equally applicable to MLED display products that the light-emitting unit 024 is a mini LED (MLED). Compared to OLED, the pixel current required for MLED is at the A level, which is approximately 100 times greater than the pixel current required for OLED. Therefore, the aspect ratio W/L of the light-emitting control transistor M0 in MLED display products is significantly larger than that in OLED display products, requiring a larger current.

In summary, embodiments of the present disclosure provide a display panel. The display panel includes a substrate having a display region and a peripheral region, a plurality of display pixels disposed within the display region, and a light-emitting control circuit disposed within the peripheral region. The display pixels emit light under the signal drive provided by the signal line, which includes a pull-up power line and a pull-down power line. The light-emitting control circuit, in response to light-emitting control signals provided by light-emitting control lines, controls the connection or disconnection of the pull-up power line or pull-down power line with the display pixels. Thus, by flexibly arranging the light-emitting control signals, the light-emitting control circuit flexibly controls the duration of the pull-up power line or pull-down power line being connected to the display pixels, thereby flexibly controlling the light-emitting duration of the display pixel. As can be known, the display panel exhibits good flexibility in driving the display pixels.

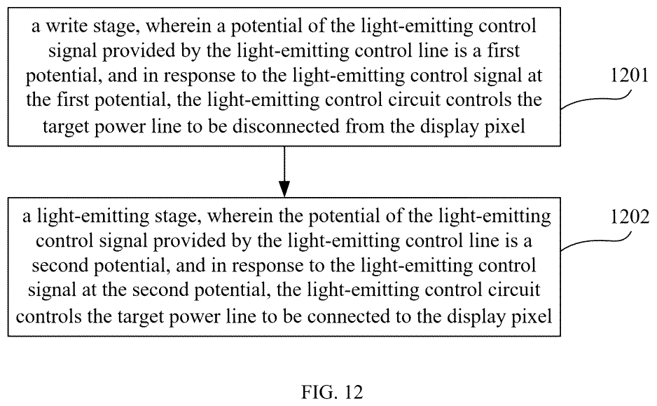

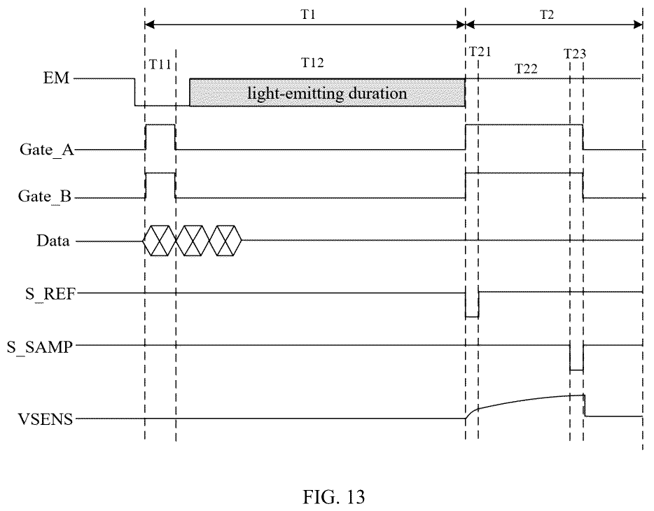

FIG. 12 is a flowchart diagram of a method for driving a display panel according to some embodiments of the present disclosure. The method is configured to drive the display panel described above. As shown in FIG. 12, the method includes the following.

In step 1201, in a writing stage, the potential of the light-emitting control signal provided by the light-emitting control line is the first potential. In response to the light-emitting control signal at the first potential, the light-emitting control circuit controls the target power line to disconnect from the display pixel.

In step 1202, in a light-emitting stage, the potential of the light-emitting control signal provided by the light-emitting control line is a second potential. In response to the light-emitting control signal at the second potential, the light-emitting control circuit controls the target power line to be connected to the display pixel.

The target power line is the pull-up power line connected to the light-emitting drive circuit of the display pixel, or the target power line is the pull-down power line connected to the light-emitting unit of the display pixel.

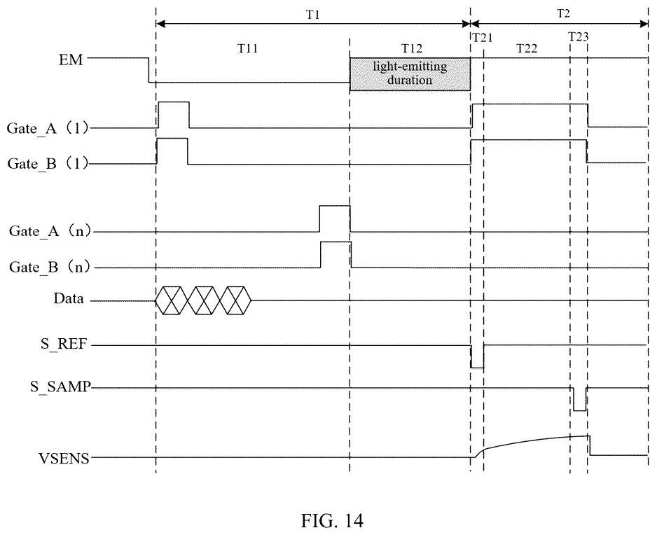

Optionally, for the plurality of light-emitting control lines connected to the plurality of light-emitting control circuits, in one implementation, the required light-emitting control signals are provided sequentially to each of the plurality of light-emitting control lines, or, in another implementation, the required light-emitting control signals are provided uniformly to all of the plurality of light-emitting control lines. In both of these implementations, as shown in the structure of FIG. 5, FIGS. 13 and 14 illustrate the signal timing diagrams of a display panel. Referring to the timing diagram, it can be seen that a frame period includes a display stage T1 and a sensing stage T2 executed sequentially. The display stage T1 includes a write stage T11 and a light-emitting stage T12 executed sequentially. The sensing stage T2 includes a reset stage T21, a compensation stage T22, and an extraction stage T23 executed sequentially.

During the write stage T11, the gate line Gate_A provides a high-potential gate drive signal, the compensation line Gate_B provides a high-potential compensation signal, and the light-emitting control line EM provides a low-potential light-emitting control signal. In the structure shown in FIG. 5, the high-potential is an effective potential, and the low-potential is an ineffective potential. Correspondingly, the data write transistor M1 and the compensation transistor M2 are turned on, and the light-emitting control transistor M0 is turned off. Furthermore, the data line Data transmits the data signal to the input node N1 via the turned-on data write transistor M1 to charge the input node N1, and the sensing line SENS transmits the reference signal to the output node N2 via the turned-on compensation transistor M2 to reset the output node N2. The storage capacitor Cst stores the data signal transmitted to the input node N1.

During the light-emitting stage T12, the gate line Gate_A provides a low-potential gate drive signal, the compensation line Gate_B provides a low-potential compensation signal, and the light-emitting control line EM provides a high-potential light-emitting control signal. Correspondingly, the data write transistor M1 and the compensation transistor M2 are turned off, and the light-emitting control transistor M0 is turned on. Furthermore, the pull-up power line VDD transmits the pull-up power supply signal to the transition node N3 through the turned-on light-emitting control transistor M0, which causes the light-emitting drive transistor M3 to transmit the light-emitting drive signal to the anode of the light-emitting unit 024 based on the pull-up power supply signal and the data signal from the input node N1, thereby causing the light-emitting unit 024 to emit light based on the light-emitting drive signal and the pull-down power supply signal provided by the pull-down power line VSS connected to the cathode. The duration of light light-emitting is positively correlated with the duration of the high-potential light-emitting control signal. That is, the longer the duration of the high-potential light-emitting control signal is, the longer the duration of light light-emitting from the light-emitting unit 024 is. This enables flexible control of the light-emitting duration of display pixel 02.

During the reset stage T21 to the extraction stage T23, the gate line Gate_A provides a high-potential gate drive signal, the compensation line Gate_B provides a high-potential compensation signal, and the light-emitting control line EM provides a high-potential light-emitting control signal. Correspondingly, the data write transistor M1, the compensation transistor M2, and the light-emitting control transistor M0 are all turned on.

Furthermore, during the reset stage T21, in the external compensation device 10, the switch control terminal S_REF connected to switch K1 provides a switch control signal with an effective potential (e.g., low-potential), and the switch control terminal S_SAMP connected to switch K2 provides a switch control signal with an ineffective potential (e.g., high-potential), causing the switch K1 to turn on and the switch K2 to turn off. As a result, the reference signal terminal V_REF and the sensing line SENS are connected, and the reference signal is transmitted to the output node N2 via the sensing line SENS and the turned-on compensation transistor M2, thereby resetting the output node N2, i.e., the anode of the light-emitting unit 024.

During the compensation stage T22, in the external compensation device 10, the switch control terminal S_REF connected to switch K1 provides a switch control signal with an invalid potential, and the switch control terminal S_SAMP connected to switch K2 provides a switch control signal with an invalid potential, causing the switch K1 and the switch K2 to close.

During the extraction stage T23, in the external compensation device 10, the switch control terminal S REF connected to switch K1 provides a switch control signal with an invalid potential, and the switch control terminal S_SAMP connected to switch K2 provides a switch control signal with a valid potential, causing the switch K1 to close and the switch K2 to open. As a result, the test terminal VSENS and the sensing line SENS are connected, and the sensing line SENS extracts the signal from the output node N2 as a sensing signal and transmits it to the test terminal VSENS, which causes the external compensation device 10 to perform external compensation on the data signal based on this sensing signal.

It is understood that, referring to FIG. 14, a plurality of gate lines Gate_A connected to a plurality of display pixels 02 sequentially provide gate drive signals with a valid potential to the plurality of display pixels 02. In the timing shown in FIG. 13, a plurality of switch control lines EM sequentially provides the switch control signals with a valid potential, that is, the light-emitting control transistors M0 connected to each row of display pixels 02 are sequentially turned on. In the timing shown in FIG. 14, the plurality of switch control lines EM are switch control signals that provide effective potential gate drive signals to all rows of display pixels 02 via the plurality of gate lines Gate_A. In the case that the data signals provided by the data lines Data are written to all rows of display pixels 02, effective potential light-emitting control signals are uniformly provided, and the light-emitting control transistors M0 connected to each row of display pixels 02 are activated simultaneously. In addition, similar to the plurality of gate lines Gate A, as shown in FIG. 14, the plurality of compensation lines Gate_B connected to the plurality of row display pixels 02 also sequentially provide compensation signals with valid potential to the plurality of row display pixels 02. The figure illustrates an example that the display panel includes n rows of display pixels 02.

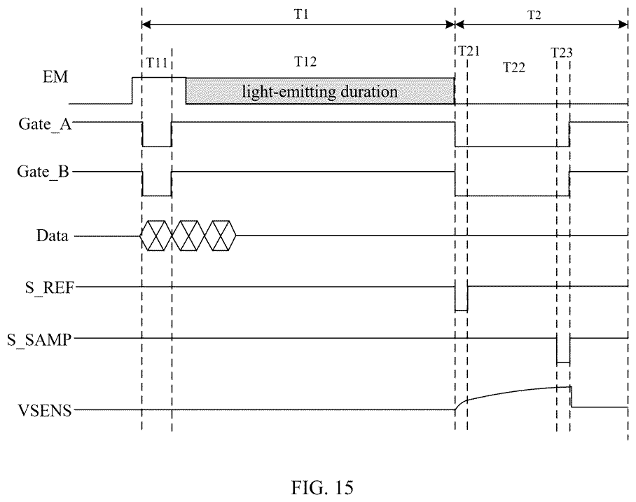

Optionally, FIG. 15 further illustrates a signal sequence diagram in a display panel using the structure shown in FIG. 8 as an example. Comparing FIGS. 13 and 14, it can be seen that, unlike the structure shown in FIG. 5, because the data write transistor M1, the compensation transistor M2, and the light-emitting control transistor M0 are all P-type transistors, the effective potentials of the gate drive signal, the compensation signal, and the light-emitting control signal all become low-potentials, while the ineffective potentials all become high-potentials.

It should be understood that because the driving method achieves essentially the same technical effects as those of the above display panel embodiments, for the sake of brevity, the technical effects of the driving method are not repeated here.

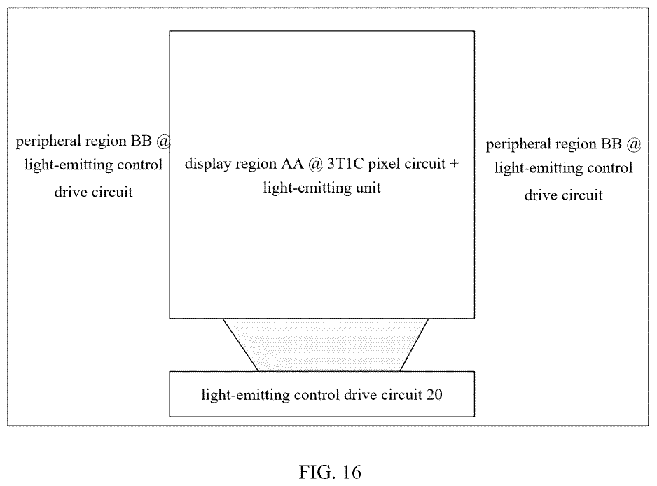

FIG. 16 is a schematic structural diagram of a display device according to some embodiments of the present disclosure. As shown in FIG. 16, the display device includes a light-emitting control drive circuit 20, and the display panel described above.

As shown in FIG. 1, the light-emitting control drive circuit 20 is connected to a plurality of light-emitting control lines EM connected to a plurality of light-emitting control circuits 03 of the display panel, and is configured to transmit light-emitting control signals to the plurality of light-emitting control lines EM.

Optionally, as an alternative implementation, as shown in FIG. 16, the light-emitting control drive circuit 20 and the display panel are independent of each other, and the light-emitting control drive circuit 20 is configured to simultaneously transmit light-emitting control signals to a plurality of light-emitting control lines EM, that is, the light-emitting control drive circuit 20 transmits light-emitting control signals that satisfy the timing shown in FIG. 14.

For example, the light-emitting control drive circuit 20 is an external integrated circuit (IC).

It should be understood that FIG. 16 schematically illustrates the display region AA in the display panel and the 3T1C pixel circuit+light-emitting unit disposed within the display region AA, the peripheral region BB, and the light-emitting control circuit disposed within the peripheral region BB.

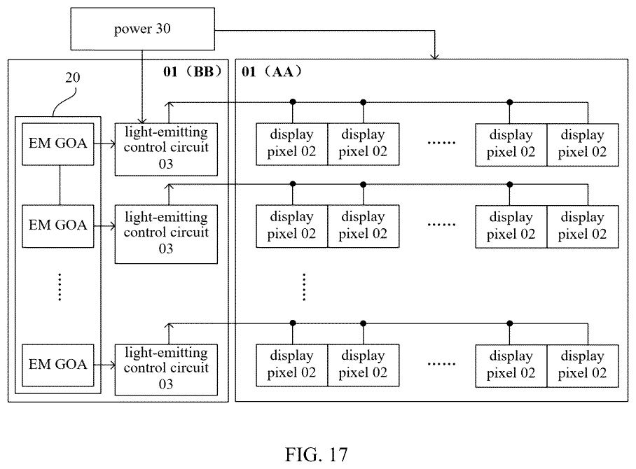

Optionally, as another alternative implementation, as shown in FIG. 17, the light-emitting control drive circuit 20 is disposed within the peripheral region BB of the substrate 01 of the display panel. For example, the light-emitting control drive circuit 20 is implemented by using gate driver on array (GOA) technology on the substrate 01, and accordingly, the light-emitting control drive circuit 20 is also referred to as an EM GOA circuit. The light-emitting control drive circuit 20 includes a cascade of a plurality of light-emitting control drive units EM GOA. The plurality of light-emitting control drive units EM GOA are connected in one-to-one correspondence with a plurality of light-emitting control lines EM and configured to sequentially transmit light-emitting control signals to the plurality of light-emitting control lines EM. That is, light-emitting control signals satisfying the timing shown in FIG. 13 are transmitted.

It should be understood that FIG. 17 also schematically illustrates a plurality of rows of display pixels 02 disposed within the display region AA, and the light-emitting control circuit 03 is connected to a single row of display pixels 02. Additionally, a power 30 is shown, which is connected to both the light-emitting control circuit 03 and the display pixels 02, and is configured to supply power to the light-emitting control circuit 03 and the display pixels 02. Furthermore, the display device further includes a gate drive circuit disposed within the peripheral region BB, i.e., the Gate GOA circuit, configured to transmit gate drive signals to the gate line Gate_A. The provision of compensation signals is similarly applicable and will not be repeated here.

Optionally, the display device may be any type of display device, such as an OLED display device or an MLED display device. Furthermore, the display device may include any product or component with display functionality, such as a mobile phone, tablet computer, television, monitor, or virtual reality (VR) device. VR display devices may produce a tailing effect when moving at high speeds or rapidly changing viewpoints, which causes two images to be simultaneously reflected in the human brain and resulting in motion blur abnormalities that impair viewing quality. In the embodiments of the present disclosure, by flexibly controlling the duration of light light-emitting, such motion blur abnormalities are effectively mitigated.

It should be understood that in the accompanying drawings, the dimensions of layers and regions may be exaggerated for clarity of illustration. Furthermore, it should be understood that when an element or layer is referred to as being “on” another element or layer, it may be directly on the other element, or there may be intermediate layers. Additionally, it should be understood that when an element or layer is referred to as being “under” another element or layer, it may be directly under the other element, or there may be one or more intermediate layers or elements. Furthermore, it should be understood that when a layer or component is referred to as being “between” two layers or two components, it may be the only layer between the two layers or components, or there may be one or more intermediate layers or components. Similar reference marks throughout the document indicates similar components.

In this application, the terms “first” and “second” are used solely for descriptive purposes and should not be construed as indicating or implying relative importance. The term “multiple” refers to two or more, unless otherwise explicitly specified.

The foregoing are only optional embodiments of the present disclosure and are not intended to limit the application, and any modifications, equivalent substitutions, improvements, or the like, within the spirit and principles of the present disclosure shall be included in the scope of protection of the present disclosure.

1. A display panel, comprising:
a substrate, having a display region and a peripheral region at least partially surrounding the display region;
a plurality of display pixels, arranged in an array within the display region, each of the plurality of display pixels comprising a data write circuit, a light-emitting drive circuit, an external compensation circuit, and a light-emitting unit, wherein the data write circuit is connected to a gate line, a data line, and an input node, the external compensation circuit is connected to a compensation line, a sensing line, and an output node, the light-emitting drive circuit is connected to the input node, the output node, and a pull-up power line, and the light-emitting unit is connected to the output node and a pull-down power line; and
a plurality of groups of light-emitting control circuits, disposed in the peripheral region, wherein each of the plurality of groups of light-emitting control circuits corresponds to at least one row of a plurality of rows of display pixels, the plurality of groups of light-emitting control circuits correspond to different rows of display pixels, and each of the plurality of groups of light-emitting control circuits comprises light-emitting control circuits disposed on at least one side of the at least one row of display pixels in a row direction, wherein the light-emitting control circuit is connected between a target power line and the at least one row of display pixels, and is connected to a light-emitting control line, and is configured to control connection or disconnection of the target power line to or from the at least one row of display pixels in response to a light-emitting control signal provided by the light-emitting control line;
wherein the target power line is the pull-down power line or the pull-up power line.

2. The display panel according to claim 1, wherein each of the plurality of groups of light-emitting control circuits corresponds to two adjacent rows of display pixels.

3. The display panel according to claim 2, wherein the light-emitting control circuit comprises an active layer, a gate metal layer, and a source-drain metal layer that are stacked sequentially on a side of the substrate;
wherein the light-emitting control circuit is connected to the at least one row of display pixels through the source-drain metal layer via a transition via, and the light-emitting control circuit is connected to two display pixels in a same column of the two adjacent rows of display pixels via a same transition via.

4. The display panel according to claim 3, wherein a thickness and a width of the source-drain metal layer satisfy: I_t/(t*b)≤a;
wherein I_t indicates a total pixel current of the plurality of display pixels connected to the light-emitting control circuit, t indicates the thickness of the source-drain metal layer, b indicates the width of the source-drain metal layer, and a indicates a maximum current density of a portion of the source-drain metal layer disposed in the transition via.

5. The display panel according to claim 1, wherein each of the plurality of groups of light-emitting control circuits comprises two light-emitting control circuits disposed on both sides of the at least one row of display pixels in the row direction respectively.

6. The display panel according to claim 5, wherein one light-emitting control circuit disposed on one side is connected to a portion of the display pixels in the at least one row of display pixels, and the other light-emitting control circuit disposed on the other side is connected to another portion of the display pixels in the at least one row of display pixels.

7. The display panel according to claim 1, wherein the light-emitting control circuit comprises a light-emitting control transistor;
a gate electrode of the light-emitting control transistor is connected to the light-emitting control line, a first electrode of the light-emitting control transistor is connected to the target power line, and a second electrode of the light-emitting control transistor is connected to the at least one row of display pixels.

8. The display panel according to claim 7, wherein the light-emitting control transistor is an N-type transistor.

9. The display panel according to claim 7, wherein the light-emitting control transistor is a dual-gate transistor.

10. The display panel according to claim 1, wherein the data write circuit comprises a data write transistor;
wherein a gate electrode of the data write transistor is connected to the gate line, a first electrode of the data write transistor is connected to the data line, and a second electrode of the data write transistor is connected to the input node.

11. The display panel according to claim 1, wherein the external compensation circuit comprises a compensation transistor;
wherein a gate electrode of the compensation transistor is connected to the compensation line, a first electrode of the compensation transistor is connected to the sensing line, and a second electrode of the compensation transistor is connected to the output node.

12. The display panel according to claim 1, wherein the light-emitting drive circuit comprises a drive transistor; wherein
in a case where the target power line is the pull-up power line, a gate electrode of the drive transistor is connected to the input node, a first electrode of the drive transistor is connected to a transition node, a second electrode of the drive transistor is connected to a first electrode of the light-emitting unit, and a second electrode of the light-emitting unit is connected to the pull-down power line; or
in a case where the target power line is the pull-down power line, the gate electrode of the drive transistor is connected to the input node, the first electrode of the drive transistor is connected to the pull-up power line, the second electrode of the drive transistor is connected to the first electrode of the light-emitting unit, and the second electrode of the light-emitting unit is connected to the transition node; and
the light-emitting control circuit is connected to the transition node.

13. The display panel according to claim 10, wherein any one of the data write transistor of the data write circuit, the compensation transistor of the external compensation circuit, or the drive transistor of the light-emitting drive circuit is an N-type transistor or a P-type transistor.

14. The display panel according to claim 13, wherein each of the plurality of display pixels further comprises a storage capacitor; wherein
in a case where the drive transistor is a P-type transistor, the target power line is the pull-down power line, and the storage capacitor is connected in series between the input node and the pull-up power line; or
in a case where the drive transistor is an N-type transistor, the target power line is the pull-up power line, and the storage capacitor is connected in series between the input node and the output node.

15. The display panel according to claim 1, wherein the display panel further comprises a plurality of dummy pixels disposed in the display region between the plurality of rows of display pixels and the plurality of groups of light-emitting control circuits.

16. The display panel according to claim 1, wherein a material of the N-type transistor of the display panel comprises an oxide material, and a material of the P-type transistors of the display panel comprises a low-temperature polysilicon material.

17. A method for driving a display panel, configured to drive a display panel, wherein the display panel comprises:
a substrate, having a display region and a peripheral region at least partially surrounding the display region;
a plurality of display pixels, arranged in an array within the display region, each of the plurality of display pixels comprising a data write circuit, a light-emitting drive circuit, an external compensation circuit, and a light-emitting unit, wherein the data write circuit is connected to a gate line, a data line, and an input node, the external compensation circuit is connected to a compensation line, a sensing line, and an output node, the light-emitting drive circuit is connected to the input node, the output node, and a pull-up power line, and the light-emitting unit is connected to the output node and a pull-down power line; and
a plurality of groups of light-emitting control circuits, disposed in the peripheral region, wherein each of the plurality of groups of light-emitting control circuits corresponds to at least one row of a plurality of rows of display pixels, the plurality of groups of light-emitting control circuits correspond to different rows of display pixels, and each of the plurality of groups of light-emitting control circuits comprises light-emitting control circuits disposed on at least one side of the at least one row of display pixels in a row direction, wherein the light-emitting control circuit is connected between a target power line and the at least one row of display pixels, and is connected to a light-emitting control line, and is configured to control connection or disconnection of the target power line to or from the at least one row of display pixels in response to a light-emitting control signal provided by the light-emitting control line;
wherein the target power line is the pull-down power line or the pull-up power line; and
the method comprises:
a write stage, wherein a potential of the light-emitting control signal provided by the light-emitting control line is a first potential, and in response to the light-emitting control signal at the first potential, the light-emitting control circuit controls the target power line to be disconnected from the display pixel; and
a light-emitting stage, wherein the potential of the light-emitting control signal provided by the light-emitting control line is a second potential, and in response to the light-emitting control signal at the second potential, the light-emitting control circuit controls the target power line to be connected to the display pixel;
wherein the target power line is the pull-up power line connected to the light-emitting drive circuit of the display pixel, or the target power line is the pull-down power line connected to the light-emitting unit of the display pixel.

18. A display device, comprising a light-emitting control drive circuit and a display panel;
wherein the display panel comprises:
a substrate, having a display region and a peripheral region at least partially surrounding the display region;
a plurality of display pixels, arranged in an array within the display region, each of the plurality of display pixels comprising a data write circuit, a light-emitting drive circuit, an external compensation circuit, and a light-emitting unit, wherein the data write circuit is connected to a gate line, a data line, and an input node, the external compensation circuit is connected to a compensation line, a sensing line, and an output node, the light-emitting drive circuit is connected to the input node, the output node, and a pull-up power line, and the light-emitting unit is connected to the output node and a pull-down power line; and
a plurality of groups of light-emitting control circuits, disposed in the peripheral region, wherein each of the plurality of groups of light-emitting control circuits corresponds to at least one row of a plurality of rows of display pixels, the plurality of groups of light-emitting control circuits correspond to different rows of display pixels, and each of the plurality of groups of light-emitting control circuits comprises light-emitting control circuits disposed on at least one side of the at least one row of display pixels in a row direction, wherein the light-emitting control circuit is connected between a target power line and the at least one row of display pixels, and is connected to a light-emitting control line, and is configured to control connection or disconnection of the target power line to or from the at least one row of display pixels in response to a light-emitting control signal provided by the light-emitting control line;
wherein the target power line is the pull-down power line or the pull-up power line; and
the light-emitting control drive circuit is connected to a plurality of light-emitting control lines connected to a plurality of light-emitting control circuits of the display panel, and is configured to transmit light-emitting control signals to the plurality of light-emitting control lines.

19. The display device according to claim 18, wherein the light-emitting control drive circuit is disposed in a peripheral region of a substrate of the display panel, and the light-emitting control drive circuit comprises a plurality of cascaded light-emitting control drive units, wherein the plurality of light-emitting control drive units are connected in one-to-one correspondence with the plurality of light-emitting control lines, and are configured to sequentially transmit the light-emitting control signals to the plurality of light-emitting control lines.

20. The display device according to claim 18, wherein the light-emitting control drive circuit is independent of the display panel, and the light-emitting control drive circuit is configured to simultaneously transmit the light-emitting control signals to the plurality of light-emitting control lines.
